(19) United States
(12) Patent Application Publication
(10) Pub. No.: US 2025/0139314 A1
(43) Pub. Date: May 1, 2025

(54) Integration of Digital Twin Scanning with Additional Digital Twin Applications

(71) Applicant: PassiveLogic, Inc., Holladay, UT (US)

(72) Inventor: Troy Aaron Harvey, Brighton, UT (US)

(21) Appl. No.: 18/496,619

(22) Filed: Oct. 27, 2023

(51) Int. Cl. G06F 30/13

(52) U.S. Cl. CPC G06F 30/13

(57) ABSTRACT

Various embodiments described herein relate to a method, an apparatus, and a non-transitory machine-readable storage medium including one or more of the following: determining that an uncommissioned device is located in a zone being scanned; pausing the scan of the zone; providing an interface for commissioning the uncommissioned device; communicating with the uncommissioned device to begin commissioning; and resuming the scan.

### TECHNICAL FIELD

Various embodiments described herein relate to creating 3D floorplans with other actions embedded and, more specifically but not exclusively, to workflows allowing integrated scanning and further actions.

### BACKGROUND

Scanning buildings involves technologies like laser scanning, photogrammetry, LiDAR, and more to capture accurate 3D models. Further actions, such as commissioning devices are achieved through BIM, IoT platforms, device management systems, commissioning software, and other tools that ensure proper configuration and integration of devices within a building's ecosystem. These processes contribute to creating smart, efficient, and well-managed buildings. However, current applications have not fully realized the untapped value in this approach

### SUMMARY

This summary is provided to introduce a selection of concepts in a simplified form that are further described below in the Detailed Description section. This summary does not identify required or essential features of the claimed subject matter. The innovation is defined with claims, and to the extent this Summary conflicts with the claims, the claims should prevail.

Various embodiments described herein relate to a method performed by a processor in communication with a memory for integrated scanning and commissioning, the method including one or more of the following: determining that an uncommissioned device is located in a zone being scanned; pausing the scan of the zone; providing an interface for commissioning the uncommissioned device; communicating with the uncommissioned device to begin commissioning; and resuming the scan. wherein an uncommissioned device is a device that needs at least one of: calibration, activation, deactivation, configuration, a firmware update, a reset, data retrieval, threshold adjustment, diagnostic testing, synchronization, maintenance, or privacy setting adjustment.

In various embodiments described herein, the determining that an uncommissioned device is located in a zone being scanned includes locating an uncommissioned device during the scanning.

In various embodiments described herein, the locating an uncommissioned device during the scanning includes, locating a real-time image of a device.

Various embodiments described herein include displaying, on a screen of a mobile device having a camera, a real-time image from the camera.

Various embodiments described herein include communicating with the uncommissioned device including using a signal to trigger the uncommissioned device.

Various embodiments described herein include the signal including one or more of sound, light, heat, a wireless signal, and radio waves.

Various embodiments described herein include receiving a signal from a user prior to resuming the scanning.

Various embodiments described herein relate to a system performed by a processor in communication with a memory for integrated scanning and commissioning, the system including one or more of the following: communicating with a controller to determine that an uncommissioned device is located in a zone being scanned while in scanning mode; automatically switching from scanning mode to commissioning mode; in commissioning mode, providing an interface for commissioning the uncommissioned device; and resuming scanning mode.

Various embodiments described herein include an uncommissioned device being a device that requires at least one of the following: calibration, activation, deactivation, configuration, a firmware update, a reset, data retrieval, threshold adjustment, diagnostic testing, synchronization, maintenance, or privacy setting adjustment.

Various embodiments described herein include that determining that an uncommissioned device is located in a zone being scanned includes receiving a message back from the controller.

Various embodiments described herein include the controller including a digital twin.

Various embodiments described herein include the digital twin updates with information about the device.

Various embodiments described herein include resume scanning mode further including automatically switching from commissioning mode to scanning mode.

Various embodiments described herein include communicating with the uncommissioned device to begin commissioning.

Various embodiments described herein relate to a machine-readable non-transitory medium encoded with instructions for execution by a processor, for integrated scanning and commissioning, the machine-readable non-transitory medium including one or more of the following: instructions for communicating with a controller to determine that an uncommissioned device is located in a zone being scanned while in scanning mode; instructions for automatically switching from scanning mode to commissioning mode; instructions for, in commissioning mode, providing an interface for commissioning the uncommissioned device; and instructions for resuming scanning mode.

Various embodiments described herein relate to instructions for sending a finished commissioning command being sent prior to resuming scanning mode.

Various embodiments described herein relate to automatically switching from commissioning mode to scanning mode after the finished commissioning command is sent.

Various embodiments described herein relate to an uncommissioned device being a device that needs at least one action, the action being: calibration, activation, deactivation, configuration, a firmware update, a reset, data retrieval, threshold adjustment, diagnostic testing, synchronization, maintenance, or privacy setting adjustment.

Various embodiments described herein relate to an action taken being dependent on context clues.

### BRIEF DESCRIPTION OF THE FIGURES

In order to better understand various example embodiments, reference is made to the accompanying drawings, wherein:

FIG. 1 illustrates an example system for implementation of various embodiments;

FIG. 2 illustrates an example system for implementing a scanning application and a commissioning application;

FIG. 3 illustrates an example digital twin for use in various embodiments;

FIG. 4A illustrates a first example of a mobile device with an interface;

FIG. 4B illustrates an example of a field device;

FIG. 4C illustrates a second example of a mobile device with an interface;

FIG. 4D illustrates a third example of a mobile device with an interface;

FIG. 4E illustrates a fourth example of a mobile device with an interface;

FIG. 4F illustrates a fifth example of a mobile device with an interface;

FIG. 5A illustrates a first example of aspects of a digital twin;

FIG. 5B illustrates a second example of aspects of a digital twin;

FIG. 5C illustrates a third example of aspects of a digital twin;

FIG. 6 illustrates an example system for implementation of various embodiments;

FIG. 7 illustrates an example method for integrated scanning and commissioning;

### DETAILED DESCRIPTION

The description and drawings presented herein illustrate various principles. It will be appreciated that those skilled in the art will be able to devise various arrangements that, although not explicitly described or shown herein, embody these principles and are included within the scope of this disclosure. As used herein, the term, “or,” as use herein, refers to a non-exclusive “or” (i.e., and/or), unless otherwise indicated (e.g., “or else” or “or in the alternative”). Additionally, the various embodiments described herein are not necessarily mutually exclusive and may be combined to produce additional embodiments that incorporate the principles described herein.

Embodiments described herein described a unified workflow that allows a user to both scan a building and simultaneously, without breaking the workflow, commission devices that need commissioning that are discovered during the scan.

3D scanning a building is essential whenever accurate, detailed, and spatially precise information is required for various purposes, ranging from design and construction to maintenance, documentation, preservation, and creating digital twins. For example, Scanning buildings assists facility managers in creating digital twins of their properties. This helps with maintenance planning, space utilization, and equipment management. For example, regular 3D scans during construction help monitor progress, identify discrepancies, and ensure that the project adheres to the design and specifications. After construction is complete, 3D scanning provides precise as-built documentation, aiding in compliance verification, quality control, and future maintenance. This assists facility managers in creating digital twins of their properties, as well as helping with maintenance planning, space utilization, and equipment utilization. More complex digital twins may be used to automate many aspects of a building, including using systems and sensors to monitor and control energy usage; adjust lighting, heating and cooling based on occupancy and environmental conditions. Digital twins may help to create an autonomous building which, among other benefits, employ smart technologies to manage energy storage, resources, and energy much more efficiently than a traditional building.

Commissioning must be done for any building that wishes to pass inspection. Certain parts of commissioning, such as commissioning sensors, is typically done using a multi-step process that involved multiple pieces of equipment. For example, a sensor may need, after installation, a configuration process, a calibration process, testing, and integration into a broader system. Certain parts of this process, such as keeping track of what sensor is installed where may be more time-consuming than expected, as a sensor may be misplaced, misnamed, etc., which may call for rechecking many similar sensors to discover where the error was made.

The ability to scan a building while simultaneously commissioning specific devices or performing other necessary functions would hold immense value in modern construction and facility management. This integrated approach would streamline the process by combining two critical tasks into a cohesive workflow. As the building's physical space is scanned and converted into a digital representation, this data can be leveraged to accurately place and configure devices within the building's layout. By commissioning devices during the scan, designers and engineers can ensure precise device placement and alignment with building infrastructure, reducing errors and minimizing post-installation adjustments. This seamless integration not only enhances efficiency during the construction phase but also lays a strong foundation for efficient device management and maintenance in the operational phase. Ultimately, this synchronized approach empowers stakeholders to achieve a higher level of accuracy, productivity, and operational readiness, translating into optimized building performance and a more seamless transition from construction to operation.

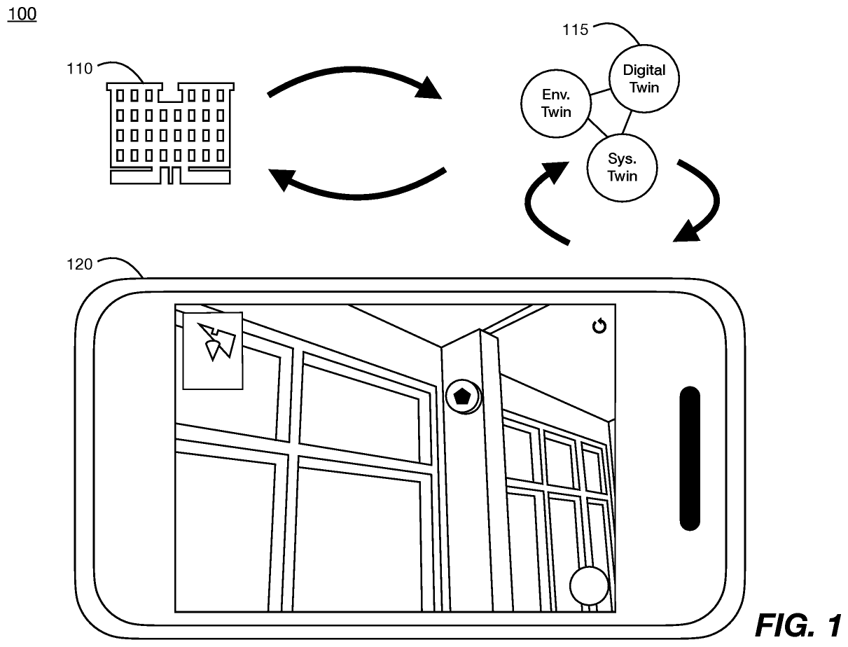

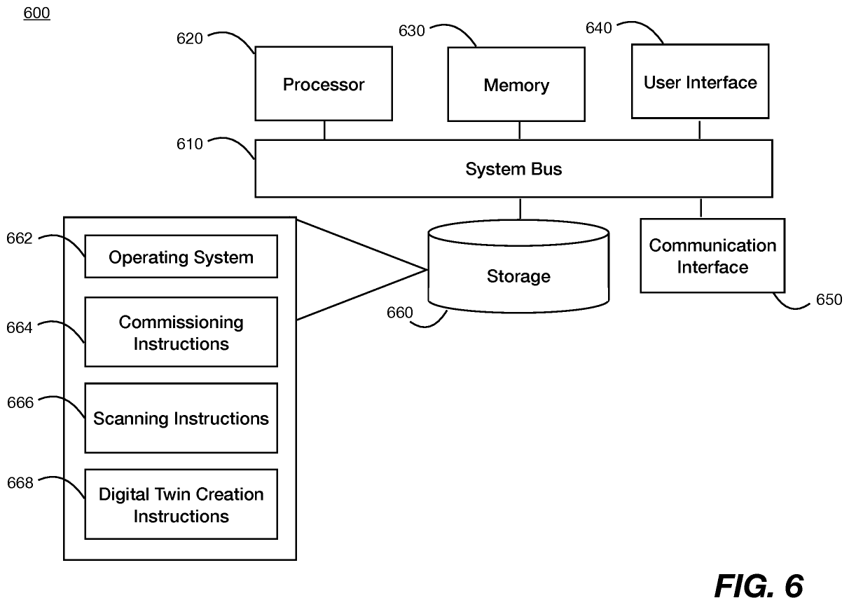

FIG. 1 illustrates an example system 100 for implementation of various embodiments. According to one specific example, system 100 may describe a controlled system 110. The controlled system has a sensor system distributed throughout, which can be thought of as its eyes and ears that gather data about its surroundings, systems, and performance. This data is then processed, sometimes in real time, and used by the digital twin 115 to make informed decisions, such as optimized energy consumption, occupant comfort, and resource utilization. These sensors may be initially installed. At some point after installation they must also be commissioned. This commissioning may take place when the building is initially scanned using a computing device 120 that is in contact with the digital twin 115. The computing device may be a mobile device, as is shown in FIG. 1. The computing device is described with more detail in FIG. 6 and the surrounding text. When a sensor is located, information about the sensor (such type, location, name, etc.) can be sent from the computing device 120 to the digital twin, and likewise, the information needed to commission the sensor can be sent from digital twin 115 to the computing device 120.

The techniques and embodiments may be applied other applications outside the context of controlled systems. Various modifications to adapt the teachings and embodiments to use in such other applications will be apparent.

It will be understood that FIG. 1 may represent a simplification in some respects. For example, in some embodiments, one or more devices may be both a controllable device, such as HVAC equipment and a sensor device. For example, a controllable pump may have an integrated sensor that reports an observed pressure back to the distributed controller system. In some embodiments, there may be multiple controllable systems 110, multiple sensor systems or other systems (not shown) involved in implementing the overall system 100, each of which may or may not be in communication with the digital twin 115. For example, the controlled system 110 may contain both an HVAC system and a lighting system, which may be implemented as two independent controllable systems controlled by two digital twins. As another example, the digital twin 115 may obtain sensor data from both a set of sensors the digital twin 115 manages and a set of sensors managed by a third party service (e.g., as may be made available through an API or other network-based service) and, as such, there may be multiple independent sensor systems that inform the operation of the digital twin 115.

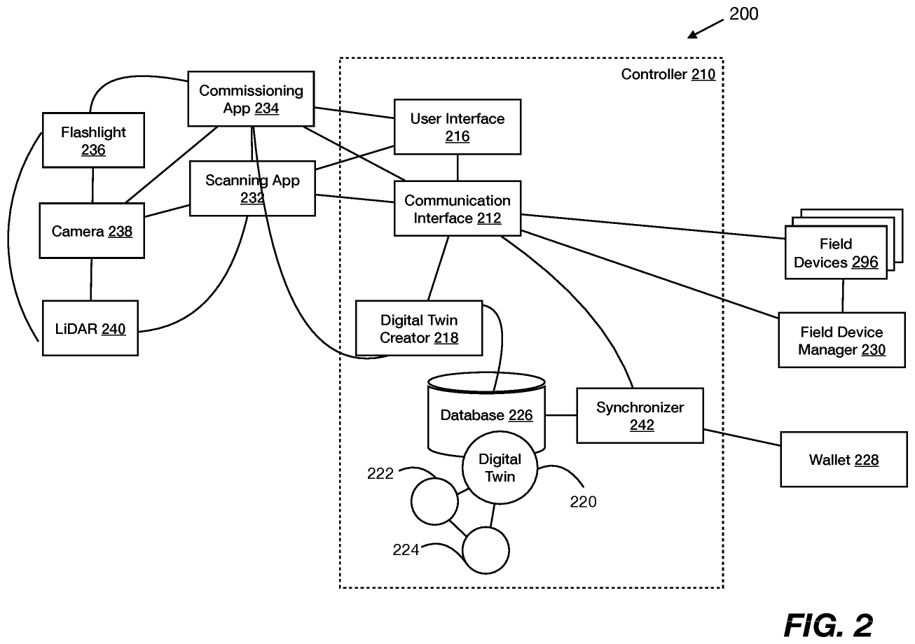

FIG. 2 illustrates an example system 200 for implementing a integrated scanning-commissioning procedure. In various embodiments, a user may 3D scan a controlled space. In such embodiments, during the building scanning process, the user employs a user interface 216 as a visual guide, functioning partially as a viewport. This interface aids in directing the scanning procedure by assisting the user in identifying the scanned portions, identifying areas that still require scanning, and, in certain implementations, gauging the accuracy of the ongoing scan. For example, the user interface 216 may include a display, a touchscreen, a keyboard, a mouse, or any device capable of performing input or output functions for a user. In some embodiments, the user interface 216 may instead or additionally allow a user to use another device for such input or output functions, such as connecting a separate tablet, mobile phone, or other device for interacting with the controller 210. The user interface 216 may be the interface associated with a mobile device, or another sort of device suitable for scanning.

Virtually any connection medium (or combination of media) may be used to enable communication between the various functions shown in FIG. 2 (e.g., the user interface 216 connection to the communications interface 212, etc.); including wired, wireless, direct, or indirect (i.e., through one or more intermediary devices, such as in a network) connections. As used herein, the term “connected” as used between two functions will be understood to encompass any form of communication capability between those functions. To enable such connections, the system 200 includes a communications interface 212. The communication interface 212 may include virtually any hardware for enabling connections as needed, such as an Ethernet network interface card (NIC), WiFi NIC, or USB connection.

According to various embodiments, the controlled system 110 utilizes a digital twin 220 that models at least a portion of the system it controls and may be stored in a database 226 along with other data. As shown, the digital twin 220 includes an environment twin 222 that models the environment whose state is being controlled (e.g., a building) and a controlled system twin 224 that models the system that the controller controls (e.g., an HVAC equipment system). A digital twin 220 may be any data structure that models a real-life object, device, system, or other entity. It will be apparent that the various techniques and embodiments described herein may be adapted to many types of digital twins, such as those that are heterogenous and omnidirectional, and other types of digital twins. Further, while the environment twin 222 and controlled system twin 224 are shown as separate structures, in various embodiments, these twins 222, 224 may be more fully integrated as a single digital twin 220. In some embodiments, additional systems, entities, devices, processes, or objects may be modeled and included as part of the digital twin 220.

The digital twin creator 218 may provide a toolkit for the user to create digital twins 220 or portions thereof. For example, the digital twin creator 218 may include a tool for defining the walls, doors, windows, floors, ventilation layout, and other aspects of a building construction to create the environment twin 222. The tool may allow for definition of properties useful in defining a digital twin 220 (e.g., for running a physics simulation using the digital twin 220) such as, for example, the materials, dimensions, or thermal characteristics of elements such as walls and windows. Such a tool may resemble a computer-aided drafting (CAD) environment in many respects. According to various embodiments, unlike typical CAD tools, the digital twin creator 218 may incorporate a 3D scanner (discussed below with reference to 232-240 in FIG. 2) that is used to input the dimensions of the controlled space 110 and location of features (such as walls, doors, windows, etc) that is transformed into the defined building structure into a digital twin 220 model that may be computable, trainable, inferenceable, and queryable, as is referenced below.

In addition or alternative to building structure, the digital twin creator 218 may provide a toolkit for defining virtually any system that may be modeled by the digital twin 220. For example, for creating the controlled system twin 224, the digital twin creator 218 may provide a drag-and-drop interface where various HVAC equipment (e.g., boilers, pumps, valves, tanks, etc.) may be placed and connected to each other, forming a system (or a group of systems) that reflect the real world controllable system 120. In some embodiments, the digital twin creator 218 may drill even further down into definition of twin elements by, for example, allowing the user to define individual pieces of equipment (along with their behaviors and properties) that may be used in the definition of systems. As such, the digital twin creator 218 provides for a composable twin, where individual elements may be “clicked” together to model higher order equipment and systems, which may then be further “clicked” together with other elements.

The digital twin creator may also accept input from a scanning tool, such as a 3D scanner, which sends it information to determine the nature of a controlled space that is to be built. This information may be in the nature of a 3D point cloud, which the digital twin creator uses to construct the shape of the space, including walls, doors, windows, etc. The digital twin may receive more direct information about the controlled space, such as dimensions of individual spaces, locations of doors and windows, etc., or it may receive some intermediate information, which it then uses to construct the controllable space.

In other embodiments, the digital twin 220 may be created by another device (e.g., by a server providing a web- or other software-as-a-service (SaaS) interface for the user to create the digital twin 220, or by a device of the user running such software locally) and later downloaded to or otherwise synced to the controller 210. In other embodiments, the digital twin 220 may be created automatically by the controller 210 through observation of the systems it controls or is otherwise in communication with. In some embodiments a combination of such techniques may be employed to produce an accurate digital twin-a first user may initially create a digital twin 220 using a SaaS service, the digital twin 220 may be downloaded to the controller 210 where a second user further refines or extends the digital twin 220 using the digital twin creator 218, and the controller 210 in operation may adjust the digital twin 220 as needed to better reflect the real observations from the systems it communicates with. Various additional techniques for defining, digesting, compiling, and utilizing a digital twin 220 according to some embodiments may be described in U.S. Pat. Nos. 10,708,078; and 10,845,771; and U.S. patent application publication numbers 2021/0383200; 2021/0383235; and 2022/0215264, the entire disclosures of which are hereby incorporated herein by reference.

In addition to storing the digital twin 220, the database 226 may store additional information that is used by the controller 210 to perform its functions. For example, the database 226 may hold tables that store sensor data. Various additional or alternative information for storage in the database 226 will be apparent. In various embodiments, the database 226 implements database replication techniques to ensure that the database 226 content is made available to additional digital twins 220 or controllers in which digital twins may reside. As such, changes that the controller 210 makes to the database 226 content (including the digital twin 220) may be made available to each of the controllers, while database changes made by the additional controllers are similarly made available in the database 226 of the controller 210 as well as the other additional controllers.

A field device manager 230 may be responsible for initiating and processing communications with field devices 296, such as sensors. As such the field device manager 230 may implement multiple functions. For sensor management, the device manager 230 may receive (via the communication interface 212 and other components, such as a semantic translator) reports of sensed data. The field device manager 230 may then process these reports and place the sensed data in the database 226 such that it is available to the other components of the controller 210. In managing sensor devices, the field device manager 230 may be configured to initiate communications with the sensor devices to, for example, establish a reporting schedule for the sensor devices and, where the sensor devices form a network for enabling such communications, the network paths that each sensor device will use for these communications. In some embodiments, the field device manager 230 may receive (e.g., as part of sensor device reports) information about the sensor health and then use this information to adjust reporting schedule or the network topology. For example, where a sensor device reports low battery or low power income, a controller 210 may instruct that sensor device to report less frequently or to move to a leaf node of the network topology so that its power is not used to perform the function of routing messages for other sensors with a better power state. Various other techniques for managing a group or swarm of sensor devices will be apparent.

In some embodiments, the field device manager 230 may perform some portions of a commissioning procedure. Accordingly, in some such embodiments, the field device manager 230 may communicate with the field devices 296 via the communication interface 212 to perform tests to verify that installation and behavior is as expected (e.g., as expected from simulations run against the digital twin 220 or from other configurations stored in the database 226 or otherwise available to a controller 210 in which the digital twin resides). In some embodiments, such as those discussed here, the field device manager 230 may communicate with a scanning application 232 or a commissioning application 234 under direction of a digital twin 220, the scanning application, the commissioning application, or a controlling processor (not shown) to commission devices. Where the field device manager 230 drives testing of field devices 296 attached instead to one or more additional controllers, the testing may include communication with the additional controllers, such as test messages that the additional controllers route to their connected field devices 296 or instructions for the additional controllers to perform testing themselves and report results thereof.

In some embodiments, the testing, which may include a portion of commissioning, performed by the field device manager 230 may be defined in a series of scripts, preprogrammed algorithms, or driven by artificial intelligence (examples of which will be explained below). Such tests may be very simple (e.g., “can a signal be read on a wire,” or “does the device respond to a simple ping message”), device specific (e.g., “is the device reporting errors according to its own testing,” “is the device reporting meaningful data,” “does the device successfully perform a test associated with its device type”), driven by the digital twin 220 (“does this device report expected data or performance when this other equipment is controlled in this way,” “when the device is controlled this way, do other devices report expected data”), at a higher system level (“does this zone of the building operate as expected,” “do these two devices work together without error”), or may have any other characteristics for verifying proper installation and functioning of a number of devices both individually and as part of higher order systems.

In some embodiments, a user may be able to define (e.g., via the user interface 216) at least some of the commissioning tests to be performed. In some embodiments, the field device manager 230 presents a graphical user interface (GUI) (e.g., via the user interface 216) for giving a user insight into the commissioning procedures of the field device manager 230. Such a GUI may provide an interface for selecting or otherwise defining testing procedures to be performed, a button or other selector for allowing a user to instruct the field device manager 230 to begin a commissioning process, an interface showing the status of an ongoing commissioning process, or a report of a completed commissioning process along with identification of which field devices 296 passed or failed commissioning, recommendations for fixing failures, or other useful statistics.

In some embodiments, the data generated by a commissioning process may be useful to further train the digital twin 220. For example, if activating a heating radiator does not cool a room as much as expected, there may be a draft or open window in the room that was not originally accounted for that can now be trained intro the digital twin 220 for improved performance. As such, in some embodiments, the field device manager 230 may log the commissioning data in a form useful to a learning engine to train the digital twin 220.

In some embodiments, the field device manager 230 may also play a role in networking. For example, the field device manager 230 may monitor the health of the network formed between the controller 210 and the additional controllers by, for example, periodically initiating test packets to be sent among the additional controllers and reported back, thereby identifying when one or more additional controllers are no longer reachable due to, e.g., a device malfunction, a device being turned off, or a network link going down. In a case where one of the additional controllers had been elected leader, the field device manager 230 may call for a new leader election among the remaining reachable additional controllers and then proceed to participate in the election according to any of various possible techniques.

In some embodiments, a 3D scanning application is used to scan a controlled space 110 using both 2D images from a camera and 3D images from a LiDAR scanner. Augmented Reality AR/LiDAR (Augmented Reality/Light Detection And Ranging) allows one to capture a detailed cloud of 3D points, with reasonable accuracy and precision, in real-time, simply by walking through a building and surveying the area with the camera. This cloud of 3D points may be automatically structured to create a 3D mesh. However, a representative LiDAR mesh appears as unstructured “triangle soup” with a lot of noise and artifacts, making it very difficult to discern the important aspects of the scene, such as a wall, from furniture, appliances, and other material present. Furthermore, the amount of raw detail makes it difficult to extract regions of interest such as walls, windows, doors, etc. For example buildings contain many flat “wall-like” surfaces which are not walls, e.g., a cupboard, making it difficult to determine a geometric criteria for designating a wall from things that are not a wall. The definition of these features heavily depends on context.

In embodiments, A 3D point cloud, or 3D mesh of the environment, is captured using a scanning application which utilizes a depth measuring system, such as LiDAR 240, simultaneously with the same environment being captured in a 2D Artificial Reality (AR) environment using a camera 238. This LiDAR device 240 and camera 238 may be on the same device, such as mobile devices shown with reference to FIG. 1 at 120. We may then use a combination of user inputs and machine learning to place annotations on the AR environment. These annotations are placed using 2D coordinates from the 3D LiDAR system. The annotations act as hints to identify the general location of features we care about. However, the initial placement of the annotations do not indicate exactly where a feature is located; rather they suggest general areas to look for in the 3D mesh to find the feature of interest. Once the 3D mesh has been completed, in a post-processing step, the 2D annotations are transformed into specific locations in the 3D space, locating the features of interest. Delaying the placement until post-processing allows significant improvements in accuracy and consistency. Various additional techniques for defining, digesting, compiling, and utilizing a digital twin 220 according to some embodiments may be described in U.S. patent application Ser. Nos. 17/722,115, 17/855,513, 17/982,321, and US patent application publication number 2023/0083703, the entire disclosures of which are hereby incorporated herein by reference.

This scanning application 232 may be reached directly through a user interface associated with the camera 238 and LiDAR 240. It may be reached through a user interface that is separate from the camera 238 and LiDAR 240, such as when working in a dangerous or otherwise difficult environment. It may also be reached through a communication interface 212 associated with field device 296, such that a field device may be able to trigger the scanning application through the communication interface 212. In some embodiments, a user interface may be used by the scanning application 232 to specify scanning actions, such as starting, stopping, continuing, etc., a scan. User annotations that may be made to a touchscreen associated with the user interface may also be sent to the scanning application through a user interface 216 which may or may not be routed through a communication interface.

In embodiments, a commissioning application 234 is used to commission field devices 296. This commissioning application may be triggered through a user interface 216, may be triggered automatically by a scanning application as discussed herein, or may be triggered in another method. The commissioning application may access a flashlight 236 associated with a computing device 120. This flashlight may be directed by the commissioning application to produce a pattern of light that commissions the uncommissioned field device 296, or another medium may be used to commission the field device 296, such as sound, etc. A camera 238 may also be used to position the flashlight 236 in the correct orientation and at the correct position for the commissioning to work properly. The flashlight 236 and camera 238 may be on the same device, such as the computing device 120, which may be a cell phone or similar device. The flashlight and camera may be on different devices. In some embodiments, the flashlight 236, camera 238, and LiDAR 240 may be on the same device which also holds the commissioning application 234 and scanning application. The commissioning application 234 may be separately located. The commissioning application 234 has access to the digital twin 220, such that the digital twin may pass information to the commissioning application 234, and receive information from the commissioning application. The digital twin may use this information to update the digital twin database 226 or other appropriate portions of programs and applications that the digital twin 220 has access to. Similarly, the commissioning application may pass information about commissioning field devices to the digital twin and receive information from the digital twin. This information may be of any sort.

The term “commissioning” should be understood broadly to include the following actions: calibration, e.g., adjusting a field device to ensure its measurements are accurate and aligned with a known reference; configuration, e.g., setting parameters of the field device such as measurement units, thresholds, sampling rates, communication settings, etc.; activating and deactivating the field device; updating internal software to enhance functionality, fix bugs, or add new features; resetting/rebooting the sensor to resolve issues, clear errors, restore default setting, etc.; retrieving data for analysis, storage, transmutation, etc.; sending data in memory from the field device to a designated recipient; modifying the trigger levels for alerts or actions based on specific readings; putting the field device into sleep mode; conducting internal tests to ensure the field device's proper functioning and to identify potential issues; synchronizing the field device's internal clock with an external reference; maintenance; adjusting field device's data collection or transmission for, e.g., privacy and other concerns, and so on.

With respect to runtime control of the field devices 296, the field device manager 230 may be responsible for issuing the commands to the field devices 296 that cause the desired action to occur. Various additional techniques for implementing a field device manager 230 according to various embodiments may be described in U.S. Pat. Nos. 11,477,905; 11,596,079; and U.S. patent application publication numbers 2022/0067226; 2022/0067227; 2022/0067230; and 2022/0070293, the entire disclosures of which are hereby incorporated herein by reference.

The wallet 228 can be used to seamlessly synchronize the digital twin with a computing device 120. If the digital twin is air gapped from the site that the scanning and commissioning is occurring at, or instant access is unavailable for some reason, the digital twin can be saved in the wallet 228 to use in the commissioning application 234 and scanning application. Similarly, after updates, the new or edited data from the scanning application and the commissioning application can be saved in the wallet 228. This mechanism proves especially beneficial for locations with stringent security protocols, such as hospitals, manufacturing plants, and government establishments. The digital twin 220/wallet 228 setup offers multiple options: it can automatically save data solely at the worksite, automatically download data exclusively at the offline site, synchronize both ways automatically, or be customized to suit the specific requirements of each site.

In specific scenarios, the wallet data is conveyed to the digital twin database 226 by means of a synchronization application 242, guaranteeing the accurate structure and data integrity during the transfer procedure. Likewise, the digital twin 220, operating through the digital twin database 226, can utilize the synchronization application 242 to transmit data to ensure that a designated application receives it in the correct format. In some instances, the data is initially in the suitable format when transmitted from either the scanning application 232 or the commissioning application. Similarly, the field devices 296 may also transmit and receive information in the same format as transmitted or received by the scanning application 232, commissioning application 234, the digital twin creator 218, or the database 226.

It will be apparent that, while particular components are shown connected to one another, this may be a simplification in some regards. For example, components that are not shown as connected may nonetheless interact. For example, the user interface 216 may provide a user with some access to the digital twin creator 218 or field device manager 230. Furthermore, in various embodiments, additional components may be included and some illustrated components may be omitted. In various embodiments, various components may be implemented in hardware, software, or a combination thereof. For example, the communications interface 212 may be a combination of communications protocol software, wired terminals, a radio transmitter/receiver, and other electronics supporting the functions thereof. As another example, the digital twin 220 may be a data structure stored in the database 226 which, in turn, may include memory chips and software for managing database organization and access. Various other implementation details will be apparent and various techniques for implementing a controller 210 and various components thereof according to some embodiments may be described in U.S. patent application publication numbers 2022/0066432; 2022/0066722; U.S. provisional patent applications 62/518,497; 62/704,976; and 63/070,460 the entire disclosures of which are hereby incorporated herein by reference.

It will be further apparent that various techniques described herein may be utilized in contexts outside of controller devices. For example, various techniques may be adapted to project planning tools, report generation, reporting dashboards, simulation software, modeling software, computer aided drafting (CAD) tools, predictive maintenance, performance optimization tools, or other applications. Various modifications for adaptation of such techniques to other applications and domains will be apparent.

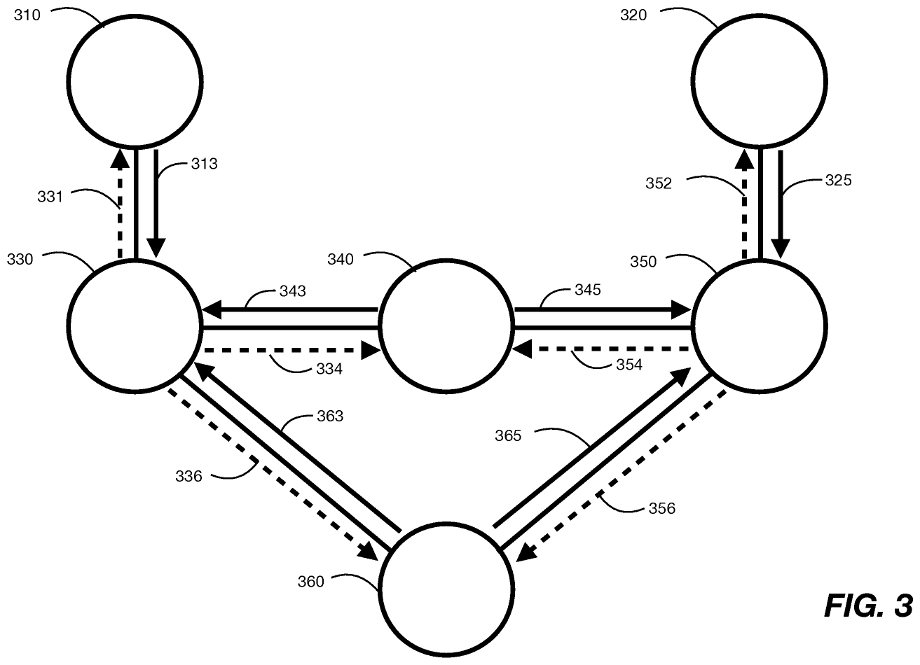

FIG. 3 illustrates an example digital twin 300 for use in various embodiments. The digital twin 300 may correspond, for example, to the digital twin 220, the environment twin 222, or the controlled system twin 224 of FIG. 2. As shown, the digital twin 300 includes a number of nodes 310, 320, 330, 340, 350, 360 connected to each other via edges. As such, the digital twin 300 may be arranged as a graph, such as a neural network. In various alternative embodiments, other arrangements may be used. Further, while the digital twin 30a may reside in storage as a graph type data structure, it will be understood that various alternative data structures may be used for the storage of a digital twin 300 as described herein. The nodes 310, 320, 330, 340, 350, 360 may correspond, for example, to aspects of the environment 110 such as HVAC zones, walls, windows, external forces (such as weather); aspects of the sensor system 130 such as individual sensors; aspects of the controllable system 120 such as controllable HVAC equipment; virtual entities, such as HVAC zone subdivisions or virtual sensors that may be assigned values through sensor fusion; or other aspects that may be used in a simulation. The edges between the nodes 310, 320, 330, 340, 350, 36a may, then, represent some relationship between the system aspects represented by the nodes 310, 320, 330, 340, 350, 360; an edge may represent, for example, physical proximity or relative location, proximity or relative location within a control loop of a system, or another relationship.

According to various embodiments, the digital twin 300 is a heterogenous neural network. Typical neural networks are formed of multiple layers of neurons interconnected to each other, each starting with the same activation function. Through training, each neuron's activation function is weighted with learned coefficients such that, in concert, the neurons cooperate to perform a function. The example digital twin 300, on the other hand, may include a set of activation functions 313, 325, 343, 345, 363, 365 that are, even before any training or learning, differentiated from each other, i.e., heterogenous. In various embodiments, the activation functions 313, 325, 343, 345, 363, 365 may be assigned based on domain knowledge related to the system being modeled. For example, the activation functions 313, 325, 343, 345, 363, 365 may include appropriate heat transfer functions for simulating the propagation of heat through a physical environment (such as function describing the radiation of heat from or through a wall of particular material and dimensions to a zone of particular dimensions). As another example, activation functions 313, 325, 343, 345, 363, 365 may include functions for modeling the operation of an HVAC system at a mathematical level (e.g., modeling the flow of fluid through a hydronic heating system and the fluid's gathering and subsequent dissipation of heat energy). Such functions may be referred to as “behaviors” assigned to the nodes 310, 320, 330, 340, 350, 360. In some embodiments, each of the activation functions 313, 325, 343, 345, 363, 365 may in fact include multiple separate functions; such an implementation may be useful when more than one aspect of a system may be modeled from node-to-node. For example, each of the activation functions 313, 325, 343, 345, 363, 365 may include a first activation function for modeling heat propagation and a second activation function for modeling humidity propagation. In some embodiments, these diverse activation functions along a single edge may be defined in opposite directions. For example, a heat propagation function may be defined from node 310 to node 330, while a humidity propagation function may be defined from node 330 to node 310. In some embodiments, the diversity of activation functions may differ from edge to edge. For example, one activation function 313 may include only a heat propagation function, another activation function 343 may include only a humidity propagation function, and yet another activation function 363 may include both a heat propagation function and a humidity propagation function.

According to various embodiments, the digital twin 300 is an omnidirectional neural network. Typical neural networks are unidirectional-they include an input layer of neurons that activate one or more hidden layers of neurons, which then activate an output layer of neurons. In use, typical neural networks use a feed-forward algorithm where information only flows from input to output, and not in any other direction. Even in deep neural networks, where other paths including cycles may be used (as in a recurrent neural network), the paths through the neural network are defined and limited. The example digital twin 300, on the other hand, may include activation functions along both directions of each edge: the previously discussed “forward” activation functions 313, 325, 343, 345, 363, 365 (shown as solid arrows) as well as a set of “backward” activation functions 331, 334, 336, 352, 354, 356 (shown as dashed arrows).

In some embodiments, at least some of the backward activation functions 331, 334, 336, 352, 354, 356 may be defined in the same way as described for the forward activation functions 313, 325, 343, 345, 363, 365—based on domain knowledge. For example, while physics-based functions can be used to model heat transfer from a surface (e.g., a wall) to a fluid volume (e.g., an HVAC zone), similar physics-based functions may be used to model heat transfer from the fluid volume to the surface. In some embodiments, some or all of the backward activation functions 331, 334, 336, 352, 354, 356 are derived using automatic differentiation techniques. Specifically, according to some embodiments, reverse mode automatic differentiation is used to compute the partial derivative of a forward activation function 313, 325, 343, 345, 363, 365 in the reverse direction. This partial derivative may then be used to traverse the graph in the opposite direction of that forward activation function 313, 325, 343, 345, 363, 365. Thus, for example, while the forward activation function 313 may be defined based on domain knowledge and allow traversal (e.g., state propagation as part of a simulation) from node 310 to node 330 in linear space, the reverse activation function 331 may be defined as a partial derivative computed from that forward activation function 313 and may allow traversal from node 330 to 310 in the derivative space. In this manner, traversal from any one node to any other node is enabled—for example, the graph may be traversed (e.g. state may be propagated) from node 340 to node 310, first through a forward activation function 343, through node 330, then through a backward activation function 331. By forming the digital twin as an omnidirectional neural network, its utility is greatly expanded; rather than being tuned for one particular task, it can be traversed in any direction to simulate different system behaviors of interest and may be “asked” many different questions.

According to various embodiments, the digital twin is an ontologically labeled neural network. In typical neural networks, individual neurons do not represent anything in particular; they simply form the mathematical sequence of functions that will be used (after training) to answer a particular question. Further, while in deep neural networks, neurons are grouped together to provide higher functionality (e.g. recurrent neural networks and convolutional neural networks), these groupings do not represent anything other than the specific functions they perform; i.e., they remain simply a sequence of operations to be performed.

The example digital twin 300, on the other hand, may ascribe meaning to each of the nodes 310, 320, 330, 340, 350, 360 and edges therebetween by way of an ontology. For example, the ontology may define each of the concepts relevant to a particular system being modeled by the digital twin 300 such that each node or connection can be labeled according to its meaning, purpose, or role in the system. In some embodiments, the ontology may be specific to the application (e.g., including specific entries for each of the various HVAC equipment, sensors, and building structures to be modeled), while in others, the ontology may be generalized in some respects. For example, rather than defining specific equipment, the ontology may define generalized “actors” (e.g., the ontology may define producer, consumer, transformer, and other actors for ascribing to nodes) that operate on “quanta” (e.g., the ontology may define fluid, thermal, mechanical, and other quanta for propagation through the model) passing through the system. Additional aspects of the ontology may allow for definition of behaviors and properties for the actors and quanta that serve to account for the relevant specifics of the object or entity being modeled. For example, through the assignment of behaviors and properties, the functional difference between one “transport” actor and another “transport” actor can be captured.

The above techniques, alone or in combination, may enable a fully-featured and robust digital twin 300, suitable for many purposes including system simulation and control path finding. The digital twin 300 may be computable and trainable like a neural network, queryable like a database, introspectable like a semantic graph, and callable like an API.

As described above, the digital twin 300 may be traversed in any direction by application of activation functions along each edge. Thus, just like a typical feedforward neural network, information can be propagated from input node(s) to output node(s). The difference is that the input and output nodes may be specifically selected on the digital twin 300 based on the question being asked, and may differ from question to question. In some embodiments, the computation may occur iteratively over a sequence of timesteps to simulate over a period of time. For example, the digital twin 300 and activation functions may be set at a particular timestep (e.g., 1 minute), such that each propagation of state simulates the changes that occur over that period of time. Thus, to simulate longer period of time or point in time further in the future (e.g., one minute), the same computation may be performed until a number of timesteps equaling the period of time have been simulated (e.g., 60 one second time steps to simulate a full minute). The relevant state over time may be captured after each iteration to produce a value curve (e.g., the predicted temperature curve at node 310 over the course of a minute) or a single value may be read after the iteration is complete (e.g., the predicted temperature at node 310 after a minute has passed). The digital twin 300 may also be inferenceable by, for example, attaching additional nodes at particular locations such that they obtain information during computation that can then be read as output (or as an intermediate value as described below).

While the forward activation functions 313, 325, 343, 345, 363, 365 may be initially set based on domain knowledge, in some embodiments training data along with a training algorithm may be used to further tune the forward activation functions 313, 325, 343, 345, 363, 365 or the backward activation functions 331, 334, 336, 352, 354, 356 to better model the real world systems represented (e.g., to account for unanticipated deviations from the plans such as gaps in venting or variance in equipment efficiency) or adapt to changes in the real world system over time (e.g., to account for equipment degradation, replacement of equipment, remodeling, opening a window, etc.).

Training may occur before active deployment of the digital twin 300 (e.g., in a lab setting based on a generic training data set) or as a learning process when the digital twin 300 has been deployed for the system it will model. To create training data for active-deployment learning, the controller 210 may observe the data made available from the real-world system being modeled (e.g., as may be provided by a sensor system 140) and log this information as a ground truth for use in training examples. To train the digital twin 300, the controller 210 may use any of various optimization or supervised learning techniques, such as a gradient descent algorithm that tunes coefficients associated with the forward activation functions 313, 325, 343, 345, 363, 365 or the backward activation functions 331, 334, 336, 352, 354, 356. The training may occur from time to time, on a scheduled basis, after gathering of a set of new training data of a particular size, in response to determining that one or more nodes or the entire system is not performing adequately (e.g., an error associated with one or more nodes 310, 320, 330, 340, 350, 360 passed a threshold or passes that threshold for a particular duration of time), in response to manual request from a user, or based on any other trigger. In this way, the digital twin 300 may be adapted to better adapt its operation to the real world operation of the systems it models, both initially and over the lifetime of its deployment, by tacking itself to the observed operation of those systems.

The digital twin 300 may be introspectable. That is, the state, behaviors, and properties of the nodes 310, 320, 330, 340, 350, 360 may be read by another program or a user. This functionality is facilitated by association of each node 310, 320, 330, 340, 350, 360 to an aspect of the system being modeled. Unlike typical neural networks where, due to the fact that neurons don't represent anything particularly the internal values are largely meaningless (or perhaps exceedingly difficult or impossible to ascribe human meaning), the internal values of the nodes 310, 320, 330, 340, 350, 360 can easily be interpreted. If an internal “temperature” property is read from node 310, it can be interpreted as the anticipated temperature of the system aspect associated with that node 310.

Through attachment of a semantic ontology, as described above, the introspectability can be extended to make the digital twin 300 queryable. That is, ontology can be used as a query language usable to specify what information is desired to be read from the digital twin 300. For example, a query may be constructed to “read all sensor temperatures from zones having a volume larger than 200 square feet and an occupancy of at least 1.” A process for querying the digital twin 300 may then be able to locate all nodes 310, 320, 330, 340, 350, 360 representing zones that having properties matching the volume and occupancy criteria, and then read out the temperature properties of each. The digital twin 300 may then additionally be callable like an API through such processes. With the ability to query and inference, canned transactions can be generated an made available to other processes that aren't designed to be familiar with the inner workings of the digital twin 300. For example, an “average zone temperature” API function could be defined and made available for other elements of the controller 210 or even external devices to make use of. In some embodiments, further transformation of the data could be baked into such canned functions. For example, in some embodiments, the digital twin 300 itself may not itself keep track of a “comfort” value, which may defined using various approaches such as the Fanger thermal comfort model. Instead, e.g., a “zone comfort” API function may be defined that extracts the relevant properties (such as temperature and humidity) from a specified zone node, computes the comfort according to the desired equation, and provides the response to the calling process or entity.

It will be appreciated that the digital twin 300 is merely an example of a possible embodiment and that many variations may be employed. In some embodiments, the number and arrangements of the nodes 310, 320, 330, 340, 350, 360 and edges therebetween may be different, either based on the controller implementation or based on the system being modeled by each deployment of the controller 210. For example, a controller deployed in one building may have a digital twin 300 organized one way to reflect that building and its systems while a controller deployed in a different building may have a digital twin 300 organized in an entirely different way because the building and its systems are different from the first building and therefore dictate a different model. Further, various embodiments of the techniques described herein may use alternative types of digital twins. For example, in some embodiments, the digital twin 300 may not be organized as a neural network and may, instead, be arranged as another type of model for one or more components of the system 100. In some such embodiments, the digital twin 300 may be a database or other data structure that simply stores descriptions of the system aspects, environmental features, or devices being modeled, such that other software has access to data representative of the real world objects and entities, or their respective arrangements, as the software performs its functions.

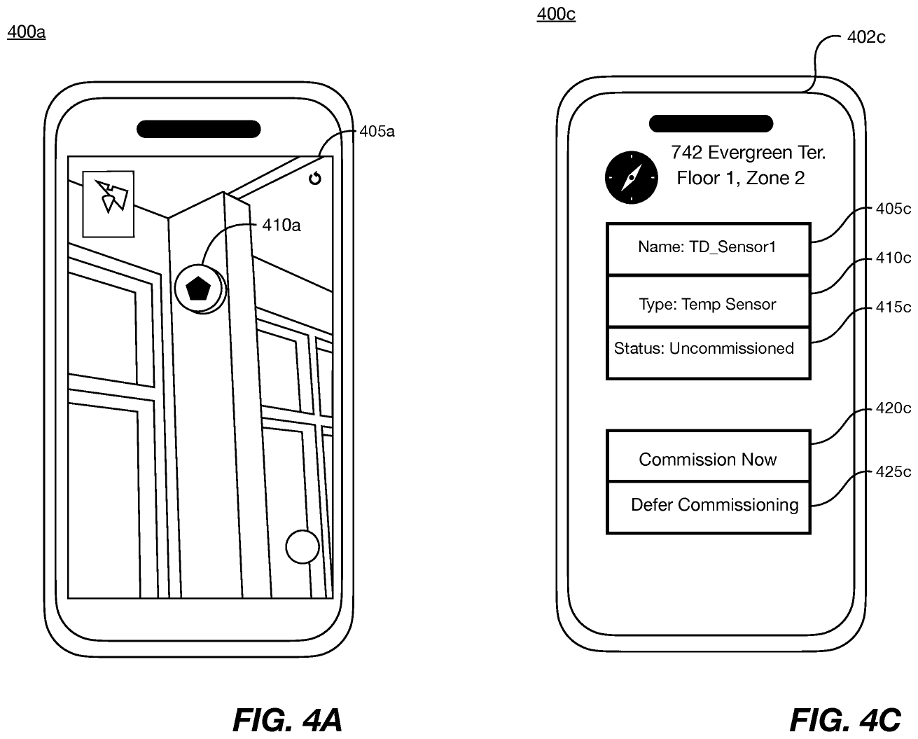

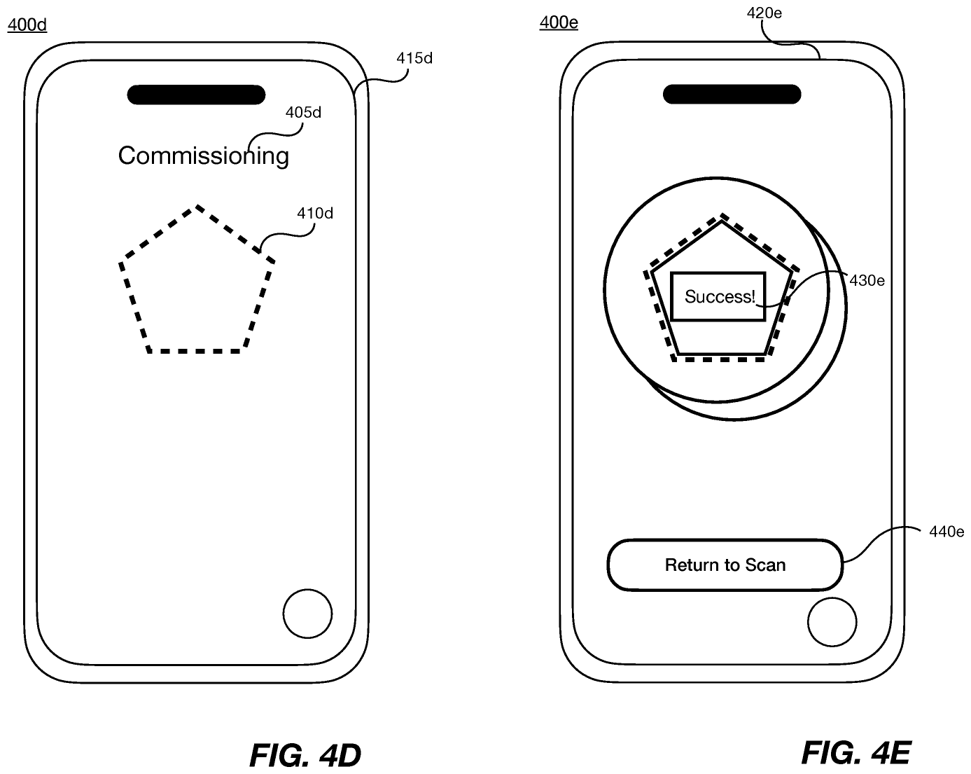

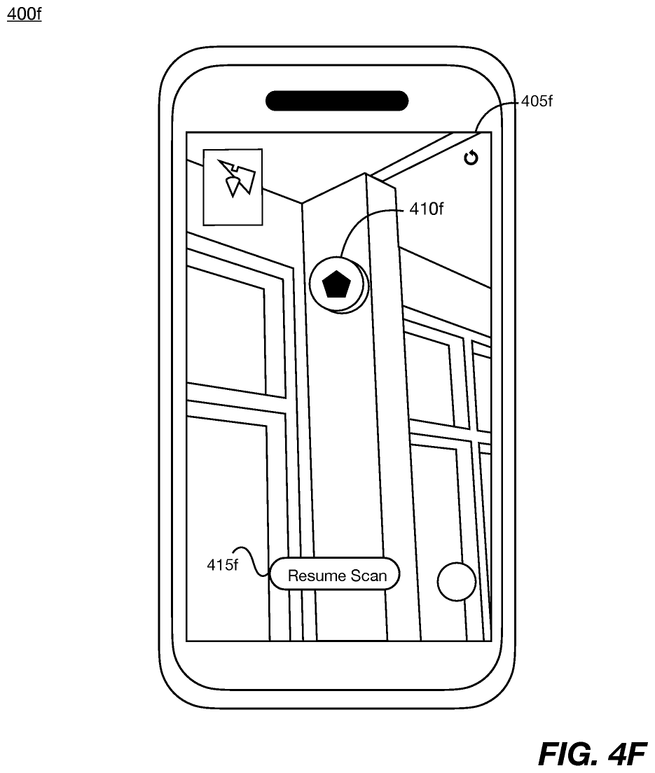

FIG. 4A discloses a 3D scanning device 400a which may be used in embodiments disclosed herein. This 3D scanning device may be equipped with a camera 238, LiDAR, and a flashlight 236. The 3D scanning device has displayed a scanning application 232, used to create a 3D digital twin version of a space using the camera 238, or the camera 238 and the LiDAR 240, as described elsewhere. The display 405a is currently showing a section of a wall with a field device 410a that is being scanned. This field device 410a may be labeled so that a camera 238 associated with the 3D scanning device 400a may recognize it. This label may be a QR code, a barcode, a near field communication (NFC) tag, an augmented reality (AR) marker, visible text, numbers, color patterns, or shapes, a geolocation marker, a digital watermark that may be visible or imperceptible to the human eye, an optical mark recognition (OMR), etc. The type of label may depend on the specific use case, the level of data required, and the capabilities of the camera, the scanning app, and the underlying software or hardware of the 3D scanning device 400a. The exemplary field device 400b is marked with an indicia 410b that may be used in some implementations to help to provide feedback for indicating when a mobile device is correctly positioned with reference to the field device 410a.

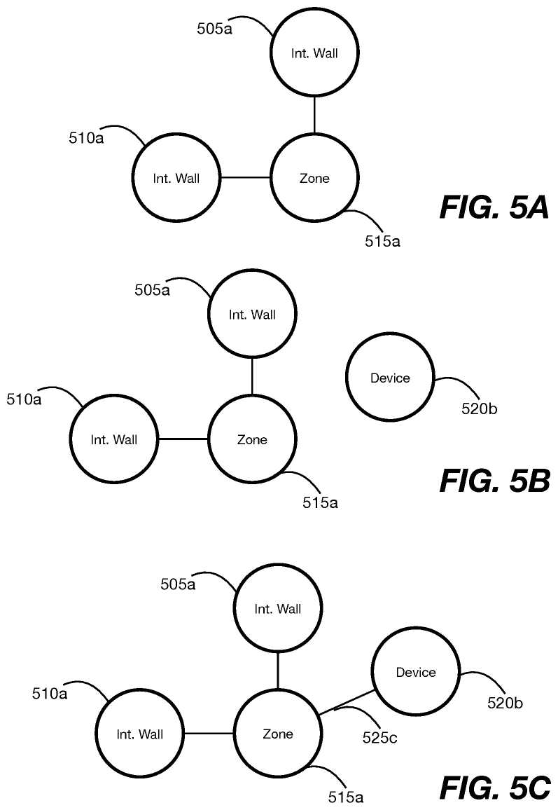

FIG. 4B illustrates a larger view 400b of the field device 410a with the indica 410b more prominently displayed. As shown, the indicia 410b is an image of a pentagon visible on the front face of the device 410a. FIG. 5A illustrates a larger view of the field device 410a, with the indicia more prominently displayed. When scanning, the scanning application 232 may register when a field device 410a with a readable label (such as the pentagon 410b) is within a certain range of the camera 238. In some embodiments, when such a field device is registered, the scanning application 232 may contact a digital twin 220, a digital twin database 226, etc. to discover the state of the field device 410a. If the field device 410a requires one or more actions that can be executed by the mobile device, the mobile device may immediately switch to an application that can perform the needed action. As used herein, the term “action” will be understood to encompass a wide range of operations that may be performed or triggered by the field device, e.g., 120, 410a, etc. For example, the action may include powering on a target device; waking a target device from a sleep state; installing software, firmware, or an update thereto on the field device; modifying a configuration of the field device; reading sensed or other gathered data from the field device; controlling or causing the field device to perform an action; testing or validating the operation of the field device; verifying the location of the field device is as expected; or causing the target device to initiate communication with one or more other devices (e.g. a controller, a digital twin 220, etc.) to affect one or more of the preceding. Any of these actions may be performed seamlessly between one application and another by the next action being anticipated by context.

In some embodiments, a user may receive a screen asking if one of the actions should be performed, delayed, or not performed at all. When more than one action is suggested, a user may be able to suggest which actions to perform, which order to perform the actions, which actions to delay, etc. When one action is to be performed, such as commissioning, the screen may switch to the new action without user intervention.

In some applications, the field device 410a may have a state that can be understood by the scanning application, such as “uncommissioned”, that can be discerned without accessing the digital twin 220 or another outside application. For example, a commissioned device may have a display with an indication of commissioning, such as an activated light, interface, etc. In such a case, when an uncommissioned (etc.) device is observed by the scanning application 232, the scanning application may take action on its own. In some applications, the field device 410a may be located in the database 226 at a different location than where the scanner found it. This information may be seamlessly passed to the database 226 from the scanning application 232 without intervention of a user.

FIG. 4C illustrates a sample action screen 402c on a mobile device 400c that may appear when a field device is registered by an application, such as a scanning application 232, has a required or optional action that may be performed. In this exemplary embodiment, the field device 410a has not been commissioned. Upon notification from a source (from the scanning application 232, the digital twin 220, or elsewhere) that the field device 410a has not been e.g., commissioned, the scanning application 232 seamlessly transitions to the commissioning application 234, maintaining the relevant state of the scanning process. This ensures that the scanning application can be resumed without interruption once the commissioning (in this case) is successfully concluded. Information about the device may be present on the commissioning screen, such as, for example, the name 405c, type of field device 410c, and status 415c. There may be a choice to commission the device now 420c, which will begin the commissioning process. A choice to defer commissioning 425c may return the mobile device 400a to the scanning application 232 screen 405a, the original location of the user when the commissioning application launched.

FIG. 4D illustrates a possible embodiment of a screen 415d of a mobile device 400d that will provide feedback for aiding a user in positioning the mobile device relative to the field device 410a that is being commissioned. In this embodiment, the mobile device 400d indicates what state it is in (“Commissioning” 405d) and displays an overlay 410d on the screen that is the same shape as or otherwise matches the indicia 410b of the field device 410a. The overlay 410d may be displayed when the mobile device 400d is in a mode where it expects or intends to initiate short range communication with the field device 410a or otherwise expects or intends to be positioned at some distance, range, or orientation relative to the field device 410a. For example, the mobile device 400d may be placed in the communication mode and display the overlay 410d in response to a scanning application 232 noticing a field device 410a that has not yet been commissioned. In such applications, the screen 400c may not appear. In some embodiments, the mobile device 400d may display the overlay after selection of the “Commission Now” button 420c of interface 400c. The user may be walked through other steps necessary for commissioning until feedback is given that the commissioning has been successful.

Once the commissioning has been successful, a display screen of a mobile device 400e may show feedback indicating that the commissioning has been a success. An example of such a display screen 420e is shown with reference to FIG. 4E at 400e. In an exemplary embodiment, the success is placed visibly on the screen 430e to provide feedback to the user. Once the action has completed, in this case, a commissioning action, the user may be directed to return to the earlier action 440e, in this case, a 3D scan.

FIG. 4E shows an exemplary screen shot of the scanning application 232 displayed on a mobile device 400e. The interface automatically returns to the original location in the scanning application 232 before the scanning application 232 was interrupted to perform a different action. Here, the screenshot 405f can be seen, essentially, to be the same screenshot 405a that was displayed prior to commissioning. In some embodiments, the now-commissioned device 410f shown greyed out in this example, may be reflected in the captured image of the building that is reflected on the mobile device screen 405f, providing feedback as to the state of the device. In some embodiments, a button or other control element 415f may be provided that invites the user to resume the scan right where it was interrupted. In some embodiments, when the action (e.g., a commissioning action) is finished, the interrupted action, here a scanning action, may resume without user action.

FIGS. 5A, 5B, and 5C illustrate possible (simplified) changes to a digital twin that may happen when a previously unassigned device is scanned and then commissioned. When a controllable space is being scanned, a digital twin may be simultaneously constructed. FIG. 5A illustrates a simple environmental digital twin 220 that may be being developed simultaneously during a 3D scan. It includes three nodes-two internal walls 505a, 510a, and a zone 515a. When the scanning application notices a field device 520b that has yet to be commissioned, that device 520b may be added (or already present but unconnected) to the digital twin device database 222. The digital twin 220 may already have information about the device that it can locate from indica on the device. In such a case the field device info may be added to a commissioning screen 400c. When the discovered field device is as-of-yet unknown to the digital twin 220, indicia on the device may indicate necessary information. Either the scanning application 232, the commissioning application 234, or a different application may add the device to the digital twin database, including locating the device within the appropriate location in the controlled space that is being 3D scanned. After the device is commissioned, the fact of the commission and any other information gleaned may be added to the digital twin, and the device may be incorporated into the digital twin, as indicated by the connection 525c. Thus, scanning and commissioning simultaneously may be a part of building a digital twin, as well as creating a 3D scan of a building and commissioning field devices.

FIG. 6 illustrates an example hardware diagram 600 for implementing a user device 120, such as a cellular phone, tablet, other mobile device, or any user device capable of being moved for short range communication with each of a number of target devices such as may be used for running a scanning. As shown, the device 600 includes a processor 620, memory 630, user interface 640, communication interface 650, and storage 660 interconnected via one or more system buses 610. It will be understood that FIG. 6 constitutes, in some respects, an abstraction and that the actual organization of the components of the device 600 may be more complex than illustrated.

The processor 620 may be any hardware device capable of executing instructions stored in memory 630 or storage 660 or otherwise processing data. As such, the processor may include a microprocessor, field programmable gate array (FPGA), application-specific integrated circuit (ASIC), a vector processor, or any other device capable of performing the logic functions described herein. In a multi-processing system, multiple processing units execute machine-executable instructions to increase processing power and as such multiple processors, as well as multiple elements with a processor, can be running simultaneously. It should be apparent, however, that in various embodiments elements belonging to the processor 620 may not be physically co-resident. For example, multiple processors may be attached to boards that are physically separate from each other.

The memory 630 may include various memories such as, for example L1, L2, or L3 cache or system memory. As such, the memory 630 may include static random access memory (SRAM), dynamic RAM (DRAM), flash memory, read only memory (ROM), or other similar memory devices. It will be apparent that, in embodiments where the processor includes one or more ASICs (or other processing devices) that implement one or more of the functions described herein in hardware, the software described as corresponding to such functionality in other embodiments may be omitted.

The user interface 640 may include one or more devices for enabling communication with a user such as a technician installing or commissioning field target devices, or a user 3D scanning a controllable space. For example, the user interface 640 may include a display and a keyboard for receiving user commands. The user interface 640 may also include a mouse. In some embodiments, such as some embodiments where the device 600 is a mobile device, the user interface may include buttons or a touchscreen interface. In some embodiments, the user interface 640 may include a command line interface or graphical user interface that may be presented to a remote terminal via the communication interface 650. Voice User Interfaces, which allow users to interact with systems using spoken commands, Augmented Reality Interfaces (sometimes referred to as Virtual Reality Interfaces, which overlay virtual elements onto a real-world environment, Gesture Based Interfaces which allow users to control computerized objects, devices, systems, etc., based on gestures, may also be used as user interfaces.

The communication interface 650 may include one or more devices for enabling communication with other hardware devices. For example, the communication interface 650 may include a network interface card (NIC) configured to communicate according to an Ethernet protocol. The communication interface 650 may include a bluetooth transmitter, receiver, antenna and specialized control chips. Additionally, the communication interface 650 may implement a TCP/IP stack for communication according to the TCP/IP protocols. The communication interface may also include various alternative or additional hardware or configurations for the communication interface 650 as will be apparent.

In some embodiments, the communication interface 650 includes hardware or firmware for short range communication with target devices. For example, the communication interface 650 may include a flashlight and firmware for transmitting an encoded message by controlling the flashlight to emit flashes of light. This may be used convey the encoded message (e.g., using Morse code or a modification thereof). As another example, the communication interface 650 may include a speaker (e.g., a speaker that is also part of the user interface 640) and firmware for transmitting an encoded message by emitting an acoustic signal via the speaker. Various other hardware and firmware for short-range communication will be apparent.

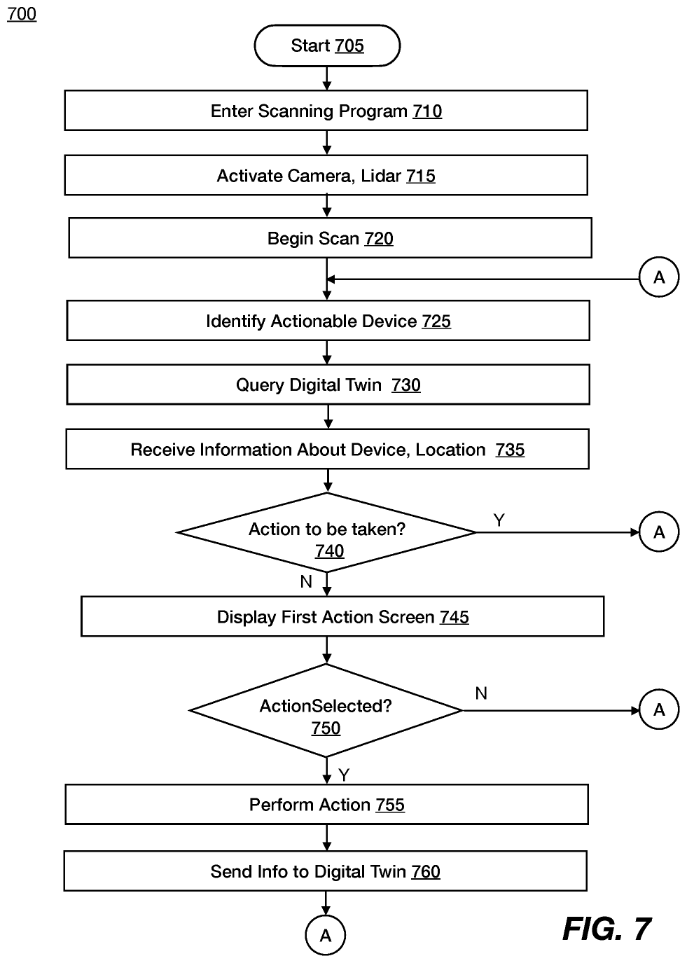

The storage 660 may include one or more machine-readable storage media such as read-only memory (ROM), random-access memory (RAM), magnetic disk storage media, optical storage media, flash-memory devices, or similar storage media. In various embodiments, the storage 660 may store instructions for execution by the processor 620 or data upon which the processor 620 may operate. For example, the storage 660 may store a base operating system 662 for controlling various basic operations of the device 600. The storage 660 may also include commissioning instructions 664 for guiding a user through commissioning a field device; scanning instructions for 3D scanning a building; and digital twin creation instructions for successively building a digital twin as the controllable space is scanned and field devices within it commissioned. Exemplary methods for implementing the commissioning instructions 664, 3D scanning instructions 666, and digital twin creation instruction 668 have been described in greater detail above with respect to FIGS. 1-5C and will be described in greater detail below with respect to FIG. 7.

It will be apparent that various information described as stored in the storage 660 may be additionally or alternatively stored in the memory 630. In this respect, the memory 630 may also be considered to constitute a “storage device” and the storage 660 may be considered a “memory.” Various other arrangements will be apparent. Further, the memory 630 and storage 660 may both be considered to be “non-transitory machine-readable media.” As used herein, the term “non-transitory” will be understood to exclude transitory signals but to include all forms of storage, including both volatile and non-volatile memories.

While the hardware device 600 is shown as including one of each described component, the various components may be duplicated in various embodiments. For example, the processor 620 may include multiple microprocessors that are configured to independently execute the methods described herein or are configured to perform steps or subroutines of the methods described herein such that the multiple processors cooperate to achieve the functionality described herein. Further, where the device 600 is implemented in a cloud computing system, the various hardware components may belong to separate physical systems. For example, the processor 620 may include a first processor in a first server and a second processor in a second server. This may be the case, for example, where the operations of the user device 600 are directed, at least in part, by a software-as-a-service application running in the cloud or on another remote server.

FIG. 7 illustrates an example of a method 700 for creating integrated scanning and commissioning. The method may be performed by a device 120, 600. The method 700 may be, in some respects, an abstraction and a general description of the operations performed by a device, a controller, or a computer for creating integrated scanning and commissioning (or other action).

The method 700 begins in step 705 and proceeds to step 710 where a 3D scanning program is started. The scanning program may be running on a user device 120, 600 with a camera and LiDAR. At step 715, the camera and the LiDAR are activated (for this commissioning action) and at step 720 the scan begins, and proceeds as shown with reference to FIG. 4A. At step 725, an actionable field device (one on which an action may be performed) is located during the scanning process, as discussed with reference to FIGS. 4A and 4B. At step 730, a digital twin associated with the current scanning process is queried for information about the actionable device. At step 735, the digital twin returns with information that it knows about the device, such as actions that may need to be taken, that are optional to take, the current location, and state of the device, whether the digital twin even knows about the device, etc. At step 740 the field device receives information about what actions are to be taken. At decision point 750, the program determines if an action were selected. An action may be selected using a user interface screenshot such as shown with reference to FIG. 4C by selecting “Commission Now”. In such case the method proceeds to step 755. An action may also not be selected. For example, a user may defer commissioning as show with reference to FIG. 4C at 425c. In such a case, the method returns to scanning mode, an example of which is shown with reference to FIG. 4F. At step 755, the device transitions from the scanning program to a program that initiates the action, as described with reference to FIGS. 4A-4C. The action is then taken, either automatically, for actions such as reading sensor values and sending them to a database 226, or under user guidance, for a more complex action, such as commissioning a field device. An example user guidance in an interface is shown with reference to FIGS. 4C-4E. At step 760, information gleaned from the action is sent to the digital twin 220. Then, the method returns to scanning mode, as shown with reference to FIG. 4F. The method continues until another actionable device is located. Of course, in portions not shown other actions may be taken, such as the user stopping the scan.

It should be apparent from the foregoing description that various example embodiments of the invention may be implemented in hardware or firmware. Furthermore, various exemplary embodiments may be implemented as instructions stored on a machine-readable storage medium, which may be read and executed by at least one processor to perform the operations described in detail herein. A machine-readable storage medium may include any mechanism for storing information in a form readable by a machine, such as a personal or laptop computer, a server, or other computing device. Thus, a machine-readable storage medium may include read-only memory (ROM), random-access memory (RAM), magnetic disk storage media, optical storage media, flash-memory devices, and similar storage media.

It should be appreciated by those skilled in the art that any block diagrams herein represent conceptual views of illustrative circuitry embodying the principles of the invention. Similarly, it will be appreciated that any flow charts, flow diagrams, and the like represent various processes which may be substantially represented in machine readable media and so executed by a computer or processor, whether or not such computer or processor is explicitly shown.

Although the various example embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the claims.

We claim:

1. A method performed by a processor for scanning a controllable space and commissioning devices within the controllable space, the method comprising:
determining that an uncommissioned device is located in a zone being scanned;
pausing the scan of the zone;
providing an interface for commissioning the uncommissioned device;
communicating with the uncommissioned device to begin commissioning; and
resuming the scan.

2. The method of claim 1, wherein an uncommissioned device is a device that needs at least one of: calibration, activation, deactivation, configuration, a firmware update, a reset, data retrieval, threshold adjustment, diagnostic testing, synchronization, maintenance, or privacy setting adjustment.

3. The method of claim 1, wherein the determining that an uncommissioned device is located in a zone being scanned comprises locating an uncommissioned device during the scanning.

4. The method of claim 3, wherein the locating an uncommissioned device during the scanning comprises, locating with a camera a real-time image of a device.

5. The method of claim 4, further comprising: displaying, on a screen of a mobile device having a camera, a real-time image from the camera.

6. The method of claim 1, wherein communicating with the uncommissioned device comprises using a signal to trigger the uncommissioned device.

7. The method of claim 6, wherein the signal comprises sound, light, heat, a wireless signal, or radio waves.

8. The method of claim 1, further comprising receiving a signal from a user prior to resuming the scanning.

9. A mobile device comprising:
a memory; and
a processor configured to:
communicate with a controller to determine that an uncommissioned device is located in a zone being scanned while in scanning mode;
automatically switch from scanning mode to commissioning mode;
in commissioning mode, provide an interface for commissioning the uncommissioned device; and
resume scanning mode.

10. The mobile device of claim 9, wherein an uncommissioned device is a device that requires at least one of the following: calibration, activation, deactivation, configuration, a firmware update, a reset, data retrieval, threshold adjustment, diagnostic testing, synchronization, maintenance, or privacy setting adjustment.

11. The mobile device of claim 10, wherein communicate with a controller comprises sending a message about the located device to the controller, and wherein determine that an uncommissioned device is located in a zone being scanned comprises receiving a message back from the controller.

12. The mobile device of claim 11, wherein the controller comprises a digital twin.

13. The mobile device of claim 12, wherein the digital twin updates with information about the device.

14. The mobile device of claim 9, wherein resume scanning mode further comprises automatically switching from commissioning mode to scanning mode.

15. The mobile device of claim 9, further comprising communicate with the uncommissioned device to begin commissioning.

16. A machine-readable non-transitory medium encoded with instructions for execution by a processor, the machine-readable non-transitory medium comprising:
instructions for communicating with a controller to determine that an uncommissioned device is located in a zone being scanned while in scanning mode;
instructions for automatically switching from scanning mode to commissioning mode;
instructions for, in commissioning mode, providing an interface for commissioning the uncommissioned device; and
instructions for resuming scanning mode.

17. The machine-readable non-transitory medium of claim 16 further comprising instructions for a sending a finished commissioning command being sent prior to resuming scanning mode.

18. The machine-readable non-transitory medium of claim 17, further comprising automatically switching from commissioning mode to scanning mode after the finished commissioning command is sent.

19. The machine-readable non-transitory medium of claim 16, wherein an uncommissioned device is a device that needs at least one action, the action comprising: calibration, activation, deactivation, configuration, a firmware update, a reset, data retrieval, threshold adjustment, diagnostic testing, synchronization, maintenance, or privacy setting adjustment.

20. The machine-readable non-transitory medium of claim 19 wherein the action taken is dependent on context clues.
